(19) United States
(12) Patent Application Publication
(10) Pub. No.: US 2020/0168593 A1
(43) Pub. Date: May 28, 2020

(54) ACTIVE BLUE LIGHT LEAKAGE PREVENTING LED STRUCTURES

(71) Applicant: CentraLED Technology Co., Ltd., Taoyuan City (TW)

(72) Inventors: Ching-Cherng SUN, Taoyuan City (TW); Tsung-Hsun YANG, Taoyuan City (TW)

(73) Assignee: CentraLED Technology Co., Ltd.

(21) Appl. No.: 16/198,849

(22) Filed: Nov. 22, 2018

(51) Int. Cl. H01L 25/16; H01L 33/62; H01L 33/50; H01L 33/58; H05B 33/08

(52) U.S. Cl. CPC H01L 25/167; H01L 33/62; H05B 33/0848; H01L 33/58; H01L 33/505

(57) ABSTRACT

The present invention discloses active blue light leakage preventing LED structures. Each of the structure includes a circuit board, at least one blue light LED die, a thermal sensor and a wavelength transformation layer, wherein the electric circuit on the circuit board receives detection signal from the thermal sensor and turns off the said blue light LED die accordingly. With the implementation of the present invention, the active blue light leakage preventing LED structure turns off the blue light LED die when it reaches its usage life span limit thus avoiding damage to human from the massive release of blue light.

### BACKGROUND OF THE INVENTION

### 1. Technical Field

The present invention relates to LED structures and, more particularly, to active blue light leakage preventing LED structures.

### 2. Description of Related Art

The earth is more and more consumed and damaged by people when the progress of living keeps advancing. Hence comes the need for the everlasting existence of the earth with the increasing demands for energy saving and environmental protection solution. Out of those demands, light-emitting diodes (LEDs) advantageously feature small physical volume, high brightness, low power consumption, and ease of use and replacement and become the most rapidly growing application.

Wherein the life span or life limit of LED, known as L70, is commonly defined as the light emitted by a LED reduces to about 70% of its stable emission value. However, in actual applications, the luminous efficiency of most white light LEDs will reduce even before L70 is reached due to the heat generated that the absorption and transformation of the fluorescent material decrease accordingly. The reduction in luminous efficiency then generates more heat. With such cycling mutual effect of heat and efficiency reduction keep going on and on, massive blue light is then inevitably leaked.

On the other hand, with the increasing usage of LEDs, more and more researches and papers about the destructive effect of blue light to human eyes are published to warn that irreversible damages will occur while human eyes are exposed to blue light for more than certain amount or for certain duration.

In view of the above, it has been a common goal and progress of the LED industries and the lighting industries to create a practical, effective and easy-to-use lighting LED structure that can rapidly, accurately and actively detect abnormal status and turn off the white light LED before massive heat is generated and great amount of blue light is emitted, and thus the protection of human eyes and life quality are thus desirably achieved, while at the same time informing the user the need of replacement of lighting device.

### SUMMARY OF THE INVENTION

The present invention discloses active blue light leakage preventing LED structures to turn off the LED when it reaches its usage life span limit thus avoiding the damage to human from the massive release of blue light.

The present invention provides an active blue light leakage preventing light-emitting diode (LED) structure, comprising: a circuit board having an upper surface; at least one blue LED die fixedly provided on the upper surface and electrically connected to the circuit board; a wavelength conversion layer fixedly provided on and covering a light output surface of the blue LED die; a power source electrically connected to the blue LED die; and a thermal sensor provided adjacent to the blue LED die, wherein when a temperature of the blue LED die rises, the thermal sensor reduces or turns off power supply from the power source to the blue LED die to prevent blue light from leaking out.

Implementation of the present invention at least involves the following inventive steps:
1. The need of complicated process or complicated equipment is not required, thus reduces implementation cost.
2. Capable of turning off the blue light LED die in time to prevent massive leakage of blue light to endanger an user.
3. Actively turn off blue light LED die to inform the user the need of replacement of lighting device, enables applications of smart controls.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE DRAWINGS

FIG. 1 is a sectional view of the active blue light leakage preventing LED structure according to the embodiment of the present invention, wherein the active blue light leakage preventing LED structure includes a thermal sensor;

FIG. 2 shows the active blue light leakage preventing LED structure in FIG. 1 further including a packaging lens;

FIG. 3 is a sectional view showing another configuration of the active blue light leakage preventing LED structure according to the embodiment of FIG. 1;

FIG. 4 shows the active blue light leakage preventing LED structure in FIG. 3 further including a packaging lens;

FIG. 5 shows the circuit diagram of the active blue light leakage preventing LED structure in one of FIG. 1 to FIG. 4;

FIG. 6A shows a circuit diagram in which a thermistor is used as the thermal sensor;

FIG. 6B shows a set of characteristic curves for the power supply and for temperature variation serving as the operation logic of the circuit in FIG. 6A;

FIG. 7A shows a circuit diagram in which a thermistor is used as the thermal sensor and which also includes a switch; and

FIG. 7B shows a set of characteristic curves for the power supply and for temperature variation serving as the operation logic of the circuit in FIG. 7A.

### DETAILED DESCRIPTION OF THE INVENTION

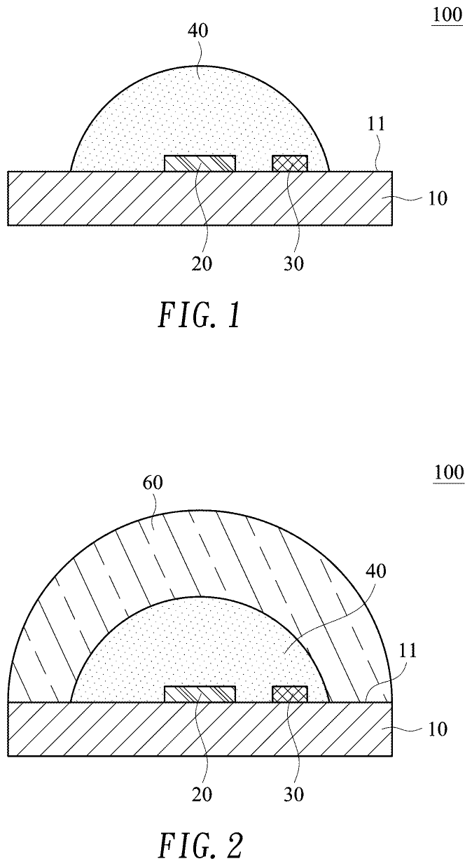

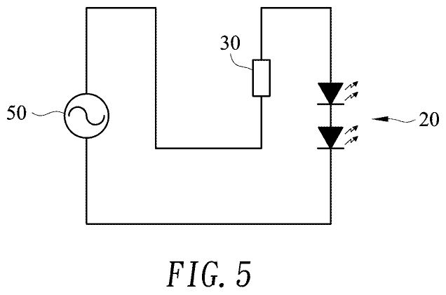

Referring to FIG. 1 to FIG. 5, the active blue light leakage preventing LED structures 100 according to this embodiment include a circuit board 10, at least one blue LED die 20 (hereinafter referred to as the blue LED die 20 for short, although a plurality of blue LED dies 20 are also feasible, as shown in FIG. 5, in which two blue LED dies 20 are provided), a thermal sensor 30, a wavelength conversion layer 40, and a power source 50.

The circuit board 10 of the active blue light leakage preventing LED structure 100 comprises an upper surface 11, and the circuit board 10 can be a FRP, ceramic, or flexible circuit board that contains at least one set of circuit path.

At least one blue light LED die 20 is provided on an upper surface 11 of the circuit board 10 and is electrically connected to the circuit board 10. The number or size or even the specification or grade of the said blue light LED die 20 that emits blue light can be chosen as required in actual applications.

The wavelength transformation layer 40, which is provided and set also on the upper surface 11 of the circuit board 10, covers the blue light LED die 20 and the thermal sensor 30. The said wavelength transformation layer 40 can be a phosphor powder layer, a quantum dot layer, or any material layer formed with photoluminescence material.

Further, the phosphor powder layer used as the wavelength transformation layer 40 can be a yellow color phosphor powder layer, a red-green mixed color phosphor powder layer, or an orange-green mixed color phosphor powder layer.

Referring to FIG. 2, the active blue light leakage preventing LED structures 100 may further include a packaging lens 60 fixedly provided on the upper surface of the circuit board 10 and covering the wavelength conversion layer 40, the blue LED die 20, and the thermal sensor 30 to from a complete LED package structure.

Wherein the said packaging lens 60 or the said wavelength transformation layer 40 can be glued on the upper surface 11 of the circuit board 10 with a gasket.

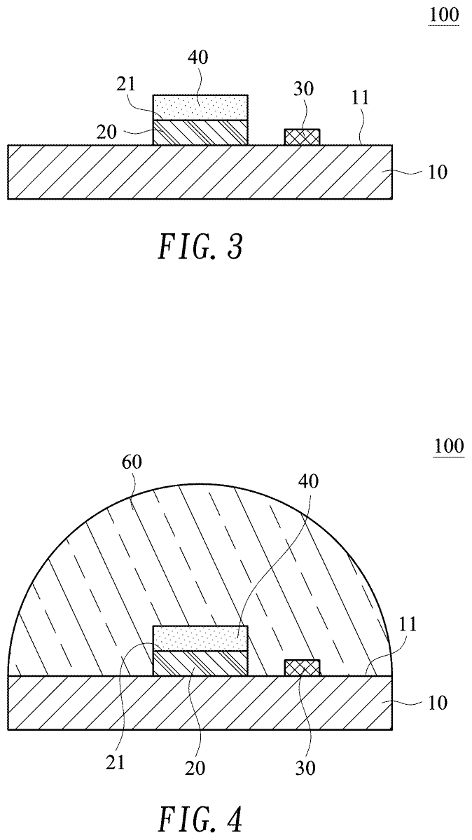

As shown in FIG. 3, the wavelength transformation layer 40 of other embodiment covers only the light emitting surface 21 of the blue light LED die 20.

As shown in FIG. 4, the active blue light leakage preventing LED structure 100 further comprises a packaging lens 60, provided and fixed on the upper surface 11 of the circuit board 10 to cover the wavelength transformation layer 40, the thermal sensor 30, and the blue light LED die 20.

As can be seen in FIG. 3 and FIG. 4, the implementation of the packaging lens 60 not only protects the wavelength transformation layer 40, the thermal sensor 30, and the blue light LED die 20 covered, also the beam shape, the focus point, the beam size or the beam divergence angle of the active blue light leakage preventing LED structure 100 can be achieved by choosing different shape or function of the packaging lens 60.

The power source 50 is electrically connected to the blue LED die 20 and serves mainly to provide the electric power needed by the blue LED die 20 during operation.

The thermal sensor 30 is provided adjacent to the blue LED die 20. When the temperature of the blue LED die 20 rises during operation, the wavelength conversion layer loses its intended effect gradually, and the amount of blue light leaking out increases as a result. The thermal sensor 30, therefore, is configured to reduce or turn off power supply from the power source 50 to the blue LED die 20 when detecting a rise in the temperature of the blue LED die 20, thereby preventing blue light from leaking out.

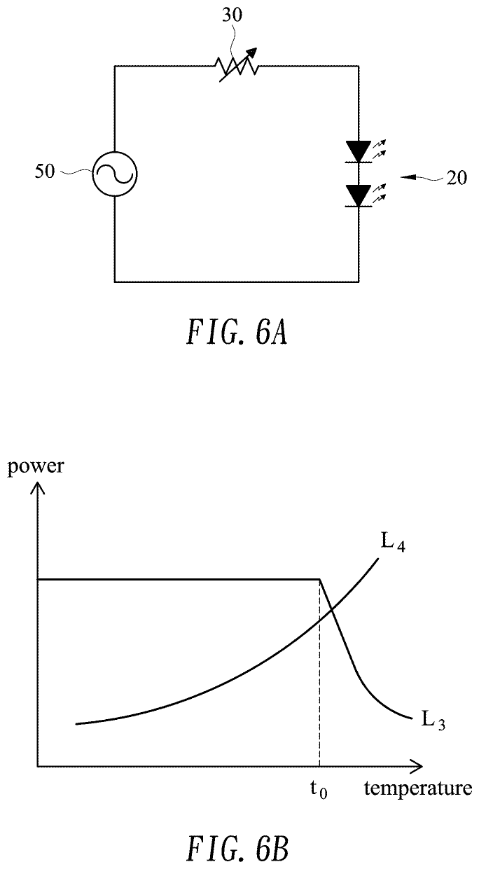

Referring to FIG. 6A and FIG. 6B, the value axis in FIG. 6B when corresponding to the curve L4 represents temperature variation detected by the thermal sensor 30. The curve L4, therefore, is a characteristic curve of the blue LED die 20 in relation to variation of its working temperature over time. The thermal sensor 30 in this embodiment is a thermistor connected in series between the blue LED die 20 and the power source 50, and the resistance of the thermistor rises with the temperature of the blue LED die 20. The thermal sensor 30 can be configured to reduce power supply from the power source 50 to the blue LED die 20 according to the characteristics of the curve L3 when the temperature of the blue LED die 20 rises, thereby preventing blue light from leaking out.

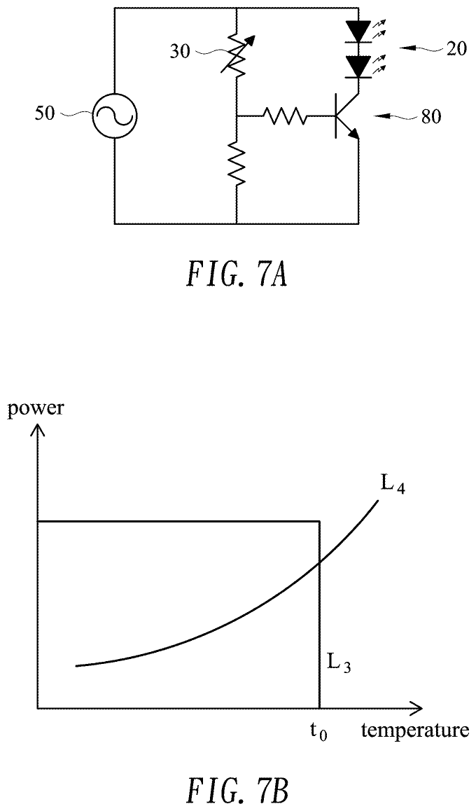

Referring to FIG. 7A and FIG. 7B, the value axis in FIG. 7B when corresponding to the curve L4 also represents temperature variation detected by the thermal sensor 30. The active blue light leakage preventing LED structure according to this embodiment may be additionally provided with a switch 80 connected in series between the blue LED die 20 and the power source 50 and use a thermistor as the thermal sensor 30 so that, when the temperature of the blue LED die 20 rises to a predetermined temperature value TO, the thermal sensor 30 turns off the switch 80 directly, thus turning off power supply from the power source 50 to the blue LED die 20 according to the characteristics of the curve L3 to prevent blue light from leaking out.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. An active blue light leakage preventing light-emitting diode (LED) structure, comprising:
a circuit board having an upper surface;
at least one blue LED die fixedly provided on the upper surface and electrically connected to the circuit board;
a wavelength conversion layer fixedly provided on and covering a light output surface of the blue LED die;
a power source electrically connected to the blue LED die; and
a thermal sensor provided adjacent to the blue LED die, wherein when a temperature of the blue LED die rises, the thermal sensor reduces or turns off power supply from the power source to the blue LED die to prevent blue light from leaking out.

2. The active blue light leakage preventing LED structure of claim 1, wherein the wavelength conversion layer is one of a phosphor powder layer, a quantum dot layer, and a layer formed of a photoluminescent material.

3. The active blue light leakage preventing LED structure of claim 1, wherein the wavelength conversion layer is a phosphor powder layer comprising one of yellow phosphor powder, a mixture of red phosphor powder and green phosphor powder, and a mixture of orange phosphor powder and green phosphor powder.

4. The active blue light leakage preventing LED structure of claim 1, further comprising a packaging lens, wherein the packaging lens is fixedly provided on the upper surface and covers the wavelength conversion layer, the blue LED die, and the thermal sensor.

5. The active blue light leakage preventing LED structure of claim 1, wherein the thermal sensor is a thermistor.

6. The active blue light leakage preventing LED structure of claim 5, wherein the thermistor is connected in series between the blue LED die and the power source, and when the temperature of the blue LED die rises, resistance of the thermistor increases to reduce power supply from the power source to the blue LED die, thereby preventing blue light from leaking out.

7. The active blue light leakage preventing LED structure of claim 5, further comprising a switch connected in series between the blue LED die and the power source, wherein when the temperature of the blue LED die rises to a predetermined temperature value, the thermistor turns off the switch to turn off power supply from the power source to the blue LED die, thereby preventing blue light from leaking out.
